(19) United States
(12) Patent Application Publication
(10) Pub. No.: US 2011/0275179 A1
(43) Pub. Date: Nov. 10, 2011

(54) PROTECTIVE TAPE JOINING METHOD AND PROTECTIVE TAPE USED THEREFOR

(76) Inventors: Tomohiro Oomure, Osaka (JP); Keisuke Watanabe, Osaka (JP); Masakazu Morimoto, Osaka (JP); Masayoshi Natsume, Osaka (JP); Tsutomu Shimura, Osaka (JP); Tsuyoshi Habu, Osaka (JP); Masayuki Yamamoto, Osaka (JP)

(21) Appl. No.: 13/144,581

(22) PCT Filed: Jul. 26, 2010
(86) PCT No.: PCT/JP2010/004752

§ 371 Date: Jul. 14, 2011

(30) Foreign Application Priority Data
Jul. 30, 2009 (JP) 2009-177833

(51) Int. Cl. H01L 21/56; C09J 7/02

(52) U.S. Cl. 438/118; 428/354; 257/E21.502

(57) ABSTRACT

Provided is an improved method of joining a protective tape having one object to suppress generation of bending of a semiconductor wafer after a back-grinding process. The protective tape is supplied toward the semiconductor wafer suction-held on a chuck table, and an intermediate sheet is supplied along an upper side of the protective tape. Then, the intermediate sheet is interposed between a joining member and the protective tape along a surface of a base material in the protective tape so as to be movable. Under this state, the joining member and the semiconductor wafer move relative to each other in a horizontal direction, whereby the protective tape is joined to a surface of the semiconductor wafer.

### TECHNICAL FIELD

This invention relates to a method for joining a protective tape to a surface of a semiconductor wafer having a circuit pattern formed thereon, and to the protective tape used for the method.

### BACKGROUND ART

A semiconductor wafer (hereinafter, simply referred to as a “wafer”) is processed as under. That is, the wafer has a surface having many chips formed thereon. In a back grinding process, a rear face of the wafer is ground. In a subsequent dicing process, the wafer is diced into each chips. The wafer tends to be thinned to have a thickness of 100 μm to 50 μm or even less in recent years with a need for a high-density package.

Here, the protective tape is joined to the surface of the wafer upon thinning of the wafer in the back grinding process for the purposes of protection of the circuit surface of the wafer, prevention of the wafer from being subject to grinding stress upon the back grinding processing, and reinforcement of the thinned wafer through back grinding.

The method of joining a protective tape to the surface of the wafer includes, for example, supplying a strip protective tape having an adhesive surface thereof being directed downward above the wafer suction-held on a chuck table having the surface thereof being directed upward. A joining roller rolls on the surface of the protective tape to join the protective tape to the surface of the wafer. Subsequently, a cutter blade of a tape cutting device pierces the protective tape and moves along an outer periphery of the wafer, allowing the joined protective tape to be cut along a contour of the wafer. Thereafter, an unnecessary portion of the tape cut out along the contour of the wafer is wound and collected (see Patent Literature 1.)

[Patent Literature 1]

Japanese Patent Publication No. 2005-116711

### DISCLOSURE OF THE INVENTION

### Summary of the Invention

The above conventional method, however, has the following problems.

Specifically, when the joining roller rolls to join the protective to the surface of the wafer, the protective tape extends in a joining direction under the influence such as tension in the protective tape, sliding contact resistance (friction force) in a joining direction that occurs between the protective tape and the joining roller, and tension on the protective tape due to curvature of the joining roller. Here, stress in a contraction direction is accumulated in the protective tape. In the case where the back grinding process is performed to the wafer while a contraction stress is accumulated in the protective tape as above, a problem arises that the thinned wafer with reduced rigidity has a surface side to which the protective tape is joined (a surface side of the wafer) that bows inward due to contraction force in the protective tape.

The wafer with the protective tape that is subjected to the back grinding process is suction-held from the surface side of the wafer for transportation in various subsequent processes. Accordingly, the wafer that bows inwardly and bends largely toward the surface thereof is poorly suction-held, which additionally leads to error of transportation or dropping and damages of the wafer during transportation.

This invention has been made regarding the state of the art noted above, and its primary object is to provide a protective tape joining method that allows suppressing of bending of a semiconductor wafer that undergoes a back grinding process, and a protective tape used therefor.

### Means for Solving the Problem

This invention is constituted as stated below to achieve the above object. This invention relates to a method of joining a protective tape to a semiconductor wafer with use of a joining member, in which the protective tape is joined to the semiconductor wafer through relative movement of the joining member and the semiconductor wafer while an intermediate sheet is interposed between the joining member and the protective tape.

According to this method, pressure perpendicular to the surface of the wafer may be applied to the protective tape without applying sliding contact resistance (friction force) in the joining direction on the protective tape that occurs between the intermediate sheet and the joining member. Consequently, suppression may be made of extension of the protective tape in the joining direction that possibly occurs due to friction force. Thus, the protective tape may be joined to the surface of the wafer with possibly reduced contraction stress to be accumulated. As a result, the wafer will not bend even when the wafer is thinned and has reduced rigidity through performance of the back grinding process to the wafer having the protective tape already joined thereto. In the foregoing embodiment, the joining member is for example a joining roller. The joining roller and the semiconductor wafer move relative to each other in a horizontal direction along the surface of the wafer.

According to this method, upon rolling of the joining roller while pressing, the intermediate sheet absorbs pressure in a rolling direction.

Moreover, the protective tape may be joined through modification of the existing protective tape joining apparatus that adopts a joining roller.

Moreover, in the foregoing embodiment, the joining member is for example a member having a curved press surface that bends outward toward the semiconductor wafer. The joining member swings, thereby pressing the curved press surface from one end to the other end thereof against the intermediate sheet.

According to this method, the intermediate sheet and the protective tape are pressed on the curved press surface of the joining member having large curvature. Consequently, no application is made to the protective tape of pressure in the horizontal direction that occurs upon rolling of the roller and sliding contact resistance (friction force) in the joining direction on the protective tape that occurs between the intermediate sheet and the joining member. As a result, only pressure perpendicular to the surface of the wafer may be applied to the protective tape, which may realize further reduced contraction force that is accumulated in the protective tape.

Moreover, in the foregoing embodiment, the protective tape is for example strip. The protective tape is integrated with the strip intermediate sheet for supply of them into a joining position.

According to this method, the protective tape having a separator on the adhesive surface thereof is integrated with the intermediate sheet. Consequently, the protective tape having the separator already removed therefrom and the intermediate sheet may be supplied simultaneously into a joining position thereof to the semiconductor wafer from an original master roll in which the protective tape and the intermediate sheet are wound together.

Moreover, in the foregoing embodiment, the protective tape is joined to the semiconductor wafer, and thereafter, the intermediate sheet and the protective tape are cut along the contour of the semiconductor wafer while the intermediate sheet is laminated on the protective tape.

According to this method, there is no need for providing an intermediate sheet removal process between a protective tape joining process and a protective tape cutting process. The protective tape joining process and the protective tape cutting process may be performed with similar efficiency as usual. The cut intermediate sheet after lamination on the protective tape may be removed appropriately from unloading of the wafer to the subsequent process.

Moreover, in the foregoing embodiment, the protective tape may be cut in advance along the contour of the semiconductor wafer.

Moreover, in the foregoing embodiment, the protective tape is joined to the semiconductor wafer, and thereafter, the intermediate sheet is removed and the protective tape is cut along the contour of the semiconductor wafer.

According to this method, the protective tape may be cut in the conventional order with use of the protective tape cutting mechanism provided in the conventional protective tape joining apparatus.

Moreover, in the foregoing embodiment, the protective tape has a separator on an adhesive surface thereof. The separator removed from the protective tape is guided between the protective tape and the joining member for use as the intermediate sheet.

According to this method, there is no need for preparation of an exclusive intermediate sheet. The separator may be separated that is joined to the adhesive surface of the protective tape of the type conventionally used. The separator is reusable as the intermediate sheet. Consequently, operation with low processing cost may be realized.

Moreover, in the foregoing embodiment, the intermediate sheet may be suspended in a tensioned condition over a protective tape joining position as to follow a feed-out angle of the protective tape that varies through rolling of the joining roller.

According to this method, the intermediate sheet is reusable.

Moreover, in the foregoing embodiment, the intermediate sheet is a tube body having a diameter larger than that of the joining roller and a width larger than the contour of the semiconductor wafer. The protective tape is joined to the surface of the wafer while the joining roller and the semiconductor wafer move relatively in the horizontal direction along the surface of the wafer with the joining roller being inserted into the tube body.

According to this method, the intermediate sheet rolls in a free state outside of the joining roller in accordance with rolling of the joining roller. That is, the joining roller applies pressure in the horizontal direction to the intermediate sheet prior to the protective tape. Consequently, the intermediate sheet is loose in a free state and fed out in the direction where the roller rolls, thereby absorbing pressure in the horizontal direction. That is, contraction force may be suppressed that is accumulated in the protective tape.

Moreover, in the foregoing embodiment, the protective tape may be joined to the semiconductor wafer while the joining roller rolls on a ring intermediate sheet that is wound over at least one pivoted idling roller and the joining roller.

According to this method, the joining roller exerts pressure in the rolling direction, and the ring intermediate sheet in a free state is slipped by the idling roller. Accordingly, only pressure in the perpendicular direction is applied to the protective tape. Moreover, the intermediate sheet is reusable through usage only upon joining of the protective tape. Accordingly, an amount of the intermediate sheet to be disposed may be reduced.

Moreover, the protective tape used in the foregoing embodiment preferably includes an intermediate sheet that allows movement on a surface of a base material in a surface direction of the base material upon exertion of pressure.

With this configuration, the protective tape and the intermediate sheet may be wound together to obtain an original master roll. That is, the original master roll may be attached to a bobbin for usage that is provided in a tape supply section in the existing protective tape joining apparatus. Where the surface of the intermediate sheet is not subjected to a release treatment, the separator is preferably joined to the adhesive surface of the protective tape. Where the protective tape has the separator, the separator is to be removed upon feeding out the protective tape.

### Effect of the Invention

As noted above, with the method of joining the protective tape according to this invention, the protective tape may be joined to the surface of the wafer with possibly reduced contraction stress accumulated in the protective tape. The thinned semiconductor wafer through the back grinding process may be suppressed from bending due to contraction force in the protective tape.

### BRIEF DESCRIPTION OF THE DRAWINGS

FIGS. 1 to 4 are schematic views each showing a process of joining a protective tape.

FIG. 5 is a schematic view of another embodiment.

FIGS. 6 to 10 are schematic views each showing a process of joining a protective tape according to another embodiment.

FIG. 11 is a sectional view showing a configuration of the protective tape according to another embodiment.

FIGS. 12 to 15 are schematic views each showing a process of joining a protective tape according to another embodiment.

### DESCRIPTION OF REFERENCES

18 . . . joining member

f . . . curved press surface

s . . . separator

T . . . protective tape

TS . . . intermediate sheet

W . . . semiconductor wafer

### BEST MODE FOR CARRYING OUT THE INVENTION

One embodiment of this invention is now to be described below with reference to the drawings.

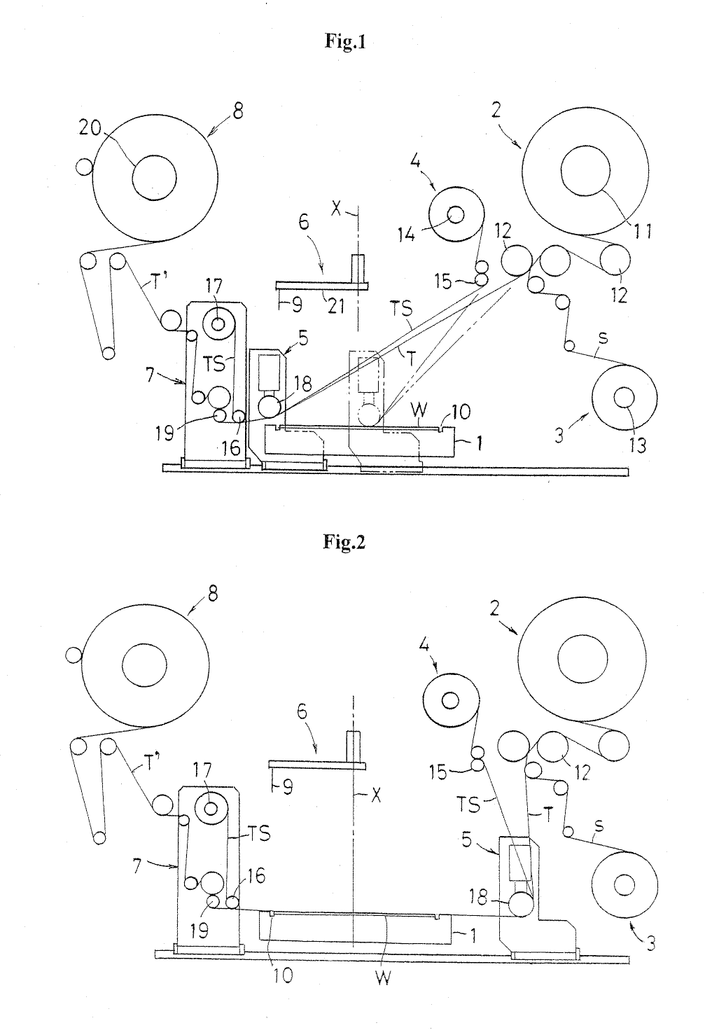

FIGS. 1 to 4 each show a schematic configuration of protective tape joining apparatus and processes of joining a protective tape for accomplishing the method according to this invention.

The protective tape joining apparatus includes a chuck table 1 that suction-holds a semiconductor wafer W (hereinafter, simply referred to as a “wafer W”) placed thereon; a tape supply section 2 that supplies a protective tape T for surface protection above the wafer W suction-held by the chuck table 1; a separator collection section 3 that separates, from the protective tape T with a separator s that is supplied from the tape supply section 2, the separator s to collect the separators; a sheet supply section 4 that supplies an intermediate sheet TS along an upper surface of the protective tape T; a joining unit 5 that joins the protective tape T to the wafer W placed on and suction-held by the chuck table 1; a protective tape cutting device 6 that cuts out the protective tape T joined to the wafer W along a contour of the wafer W; a separation unit 7 that separates an unnecessary tape T′ produced after joining to the wafer W and cutting out; a tape collection section 8 that winds up and collects the unnecessary tape T′ separated by the separation unit 7; and others. Hereinafter, description will be given of a detailed configuration of each component and device.

The wafer W is transported while being suction-held by a wafer transport device, such as a robot arm. The chuck table 1 moves upward a suction pad that lifts at a center portion of the chuck table 1 for receiving the wafer W. Subsequently, the chuck table 1 moves downward the suction pad, and thereafter aligns and places the wafer W with a circuit pattern formed on the surface thereof directed upward to suction-holds the wafer W. Moreover, a cutter traveling groove 10 is formed on the upper surface of the chuck table 1. The cutter traveling groove 10 allows a cutter blade 9 provided in the protective tape cutting device 6, mentioned later, to turn along the contour of the wafer W and to cut the protective tape T.

The tape supply section 2 has a configuration in which the protective tape T with the separator s is fed out from a supply bobbin 11, then is guided to and wound around a group of guide rollers 12, and the protective tape T with the separator s separated therefrom is guided toward the joining unit 5.

Here, the supply bobbin 11 is applied with appropriate rotational resistance in order to prevent the tape from being fed out excessively.

The separator collecting section 3 has a configuration in which a collecting bobbin 13 that winds up the separator s separated from the protective tape T rotates in a winding direction.

The sheet supply section 4 supplies the intermediate sheet TS fed out from a supply bobbin 14 that freely rotates while a guide roller 15 guides the intermediate sheet TS above the surface of the protective tape T as to face to each other, and guides the intermediate sheet TS to a guide roller 16 provided in the separation unit 7 and a rotatable winding shaft 17.

The intermediate sheet TS used herein has the same width as the protective tape T. The intermediate sheet TS preferably includes a material with either small coefficient of friction, proper elasticity, or both. For instance, a sheet of such as PET (Poly Ethylene Terephthalate), silicone rubber, and ultra-high molecular weight PET may be utilized. Moreover, the thickness thereof is not limited to one limited as a sheet, but includes a film thickness and a sheet thickness depending on the material.

The joining unit 5 has a joining roller 18 as the joining member that moves upward and downward. Moreover, the joining unit 5 reciprocates horizontally with a screw-feed type drive mechanism (not shown.)

The separation unit 7 has a separation roller 19. Moreover, the separation unit 7 reciprocates horizontally with a screw-feed type drive mechanism (not shown.)

The tape collecting section 8 has a configuration in which a collecting bobbin 20 that winds up the unnecessary tape T′ rotates in a winding direction.

The tape cutting mechanism 9 may move vertically and turn about a vertical axis X on the center of the chuck table 1. The support arm 21 provided in the protective tape cutting device 9 has at a free end thereof a cutter blade 9 having a tip end directed downward. The support arm 21 moves downward to turn about the vertical axis X, whereby the cutter blade 9 travels along the outer periphery of the wafer W for cutting out the protective tape T.

Next, with reference to FIGS. 1 to 4, description will be given of a series of basic operations for joining the protective tape T to the surface of the wafer W using the apparatus in the foregoing embodiment.

A joining command is issued, and then the wafer W pulled out from a wafer supply section, not shown, is supplied to an alignment stage, not shown, to be aligned based on a notch or an orientation mark formed at an outer periphery of the wafer.

The aligned wafer W is transported from the alignment stage to the suction pad projected from the center of the chuck table 1. Thereafter, the suction pad moves downward to place the wafer W on the chuck table 1. The chuck table 1 suction-holds the wafer W placed thereon such that the center of the chuck table 1 is aligned with a center of the wafer W. Here, as shown in FIG. 1, the joining unit 5 and the separation unit 7 are on standby in an original position on the right side. The protective tape cutting device 6 is on standby in an original position on the upper side.

Next, as shown by an imaginary line in FIG. 1, the joining roller 18 in the joining unit 5 moves downward, and presses the intermediate sheet TS and the protective tape T downward while rolling on the wafer W in the forward direction (in the right direction in plane of FIG. 1). Consequently, the protective tape T is to be joined to the entire surface of the wafer W as in FIG. 2.

In this case, the winding shaft 17 to which a rear end of the intermediate sheet TS is connected is fixed, whereas the supply bobbin 14 freely rotates. That is, when the joining roller 18 rolls forward under this state, frictional resistance in the tape joining direction and stretching force due to pressure on the peripheral surface of the joining roller 18 in a rolling direction (the horizontal direction) are exerted in the intermediate sheet TS contacting to the joining roller 18. The intermediate sheet TS, however, is movable relative to the protective tape T in the sheet longitudinal direction. Consequently, friction resistance and stretching force from the joining roller 18 are not directly exerted in the protective tape T. That is, only pressure downward in the vertical direction is exerted in the protective tape T. Accordingly, the protective tape T is joined to the surface of the wafer with an extremely little contraction stress accumulated due to stretching force, etc.

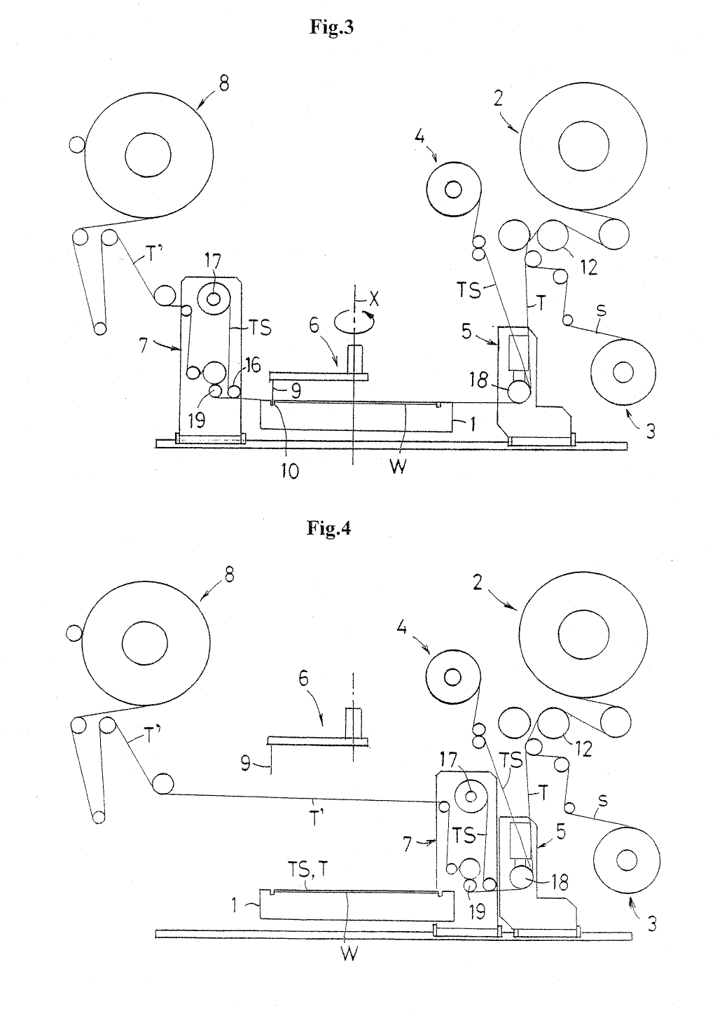

As shown in FIG. 3, when the joining unit 5 reaches a termination position, the protective tape cutting device 6 on standby on the upper side moves downward, and the cutter blade 9 pierces the intermediate sheet TS and the protective tape T on the cutter blade traveling groove 10 of the chuck table 1.

Next, the support arm 21 turns in a given direction, whereby the cutter blade 9 turns about the vertical axis X to cut the intermediate sheet TS and the protective tape T along the outer periphery of the wafer.

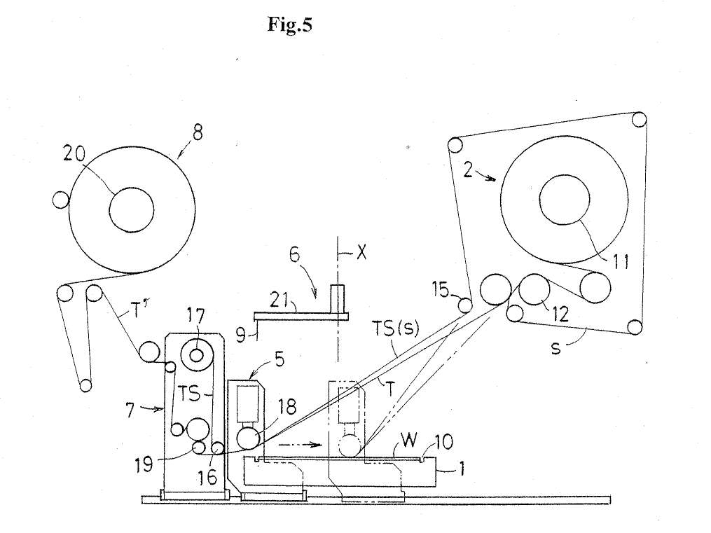

When cutting of the tapes along the outer periphery of the wafer is completed, the protective tape cutting device 6 moves upward to the original position as in FIG. 4. The separating unit 7 then moves forward while lifting up and separating the unnecessary tape T′ cut out and remaining on the wafer W.

When the separating unit 7 reaches a termination position of the separation, the separating unit 7 and the joining unit 5 move in a reverse direction so as to return to the initial positions, respectively. Here, the collecting bobbin 20 winds up the unnecessary tape T′, and the tape supplying section 2 feeds out a given amount of the protective tape T. Moreover, the winding shaft 17 winds to feed out a given amount of the intermediate sheet TS from the sheet supply section 4.

When the forgoing tape joining operation is completed, the chuck table 1 releases the suction-holding of the wafer W. Then, a transport device such as the robot arm transfers the wafer W subjected to a tape joining process to the collection section, not shown.

The intermediate sheet TS laminated on the upper surface of the protective tape and cut out may be sucked and removed from the above with use of the suction pad, or may be removed through spraying gases at a proper time during transportation of the wafer.

Thus, one tape joining process is completed as described above. Thereafter, the foregoing operation is to be repeatedly performed in succession.

In the foregoing embodiment, where the intermediate sheet TS has an extremely small thickness or low elastic modulus, rigidity of the intermediate sheet is also reduced. Accordingly, the intermediate sheet is easily caught up onto the joining roller 18 upon rolling of the joining roller, and additionally wrinkles may possibly occur in the intermediate sheet TS.

On the other hand, where the intermediate sheet TS has extremely high rigidity, bubbles may easily be caught between the intermediate sheet TS and the protective tape T.

Consequently, the thickness and elastic modulus may be changed into ones determined in advance depending on types of protective tapes T joined to the surface of the wafer W or the state of the surface of the wafer.

According to the foregoing configuration, the intermediate sheet TS is interposed between the protective tape T and the joining roller 18, and the joining roller 18 rolls on the intermediate sheet TS while pressing. Consequently, frictional force is not directly exerted in the protective tape T. Moreover, pressure in the horizontal direction as the rolling direction of the joining roller 18 is not directly exerted in the protective tape T. Thus, stretching force in the protective tape T may be avoided that possibly occurs due to both exertions. Only pressure by the joining roller 18 in the perpendicular direction may be applied to the protective tape T. Consequently, even when a back grinding process is performed to the wafer W having the protective tape joined thereto by the joining method for thinning and reduced rigidity of the wafer W, the surface of the wafer W does not bow inward under the influence of the contraction stress in the protective tape T. That is because the protective tape T has no contraction stress from the stretching force accumulated therein.

Moreover, no bending occurs in the wafer W. Accordingly, handling errors or drop of the wafer W may be avoided due to poor suction in suction-holding and transportation of the wafer W with the robot arm.

This invention is not limited to the foregoing embodiment, but may be modified as follows.

(1) As shown in FIG. 5, the separator s separated from the adhesive surface of the protective tape T may be guided on the upper surface of the protective tape T for use as the intermediate sheet TS. Here, the separator s is preferably of small coefficient of friction, proper elasticity, as mentioned above, or both.

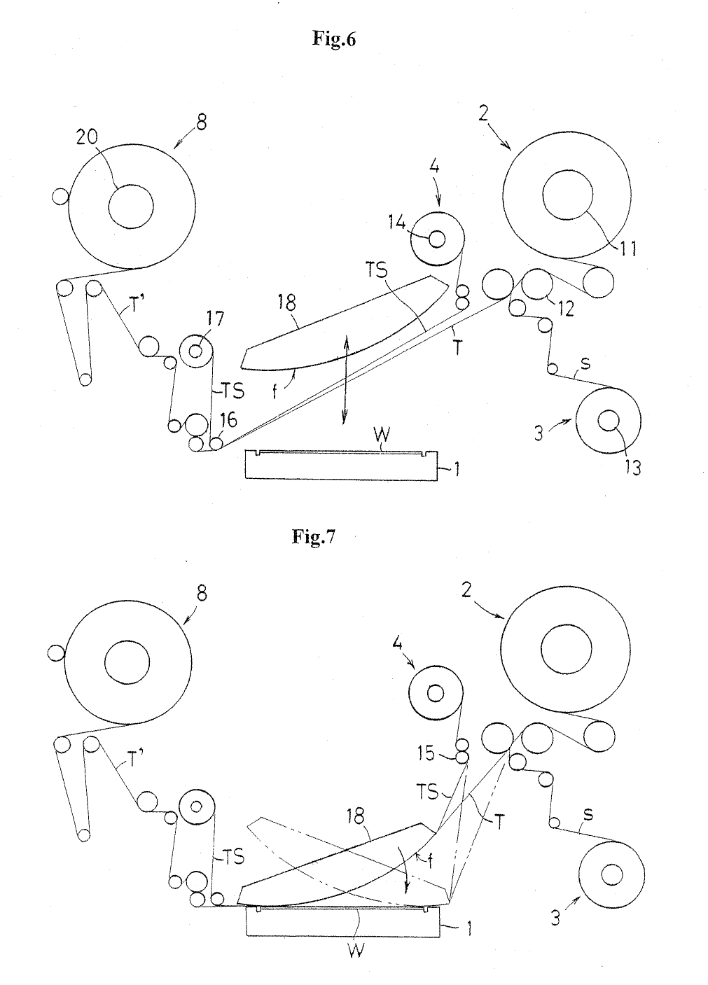

(2) As shown in FIGS. 6 and 7, a member may be used as the joining member 18 with a larger diameter than the wafer W that has a curved press surface f bowing outward toward a wafer W side. Specifically, the joining member 18 on standby that is inclined left obliquely downward moves downward to contact one end thereof to one end of the wafer W. Thereafter the joining member 18 swings, allowing to press the curved press surface f against the intermediate sheet TS from one end to the other end thereof (from the left to the right in the figures.)

The joining member 18 may be formed of silicone rubber having elasticity itself. Moreover, the joining member 18 may be made through covering a hard member with the elastic body.

According to this method, only pressure perpendicular to the surface of the wafer may be applied to the protective tape T without exerting sliding contact resistance (friction force) in the joining direction in the protective tape T that occurs between the intermediate sheet TS and the joining member 18. Moreover, the intermediate sheet TS and the protective tape T may be pressed on the curved press surface f of the joining member 18 having large curvature. Consequently, contraction stress accumulated in the protective tape T may further be reduced.

Moreover, the joining member 18 in this method may have hardness of the elastic body that gradually decreases from a joining start position toward a joining termination position. In this case, the elastic body is elastically deformed, whereby minute pressure in the horizontal direction may be absorbed that is exerted upon swing in the joining direction. Consequently, the protective tape T may be joined to the wafer W without further accumulating contraction stress in the protective tape T.

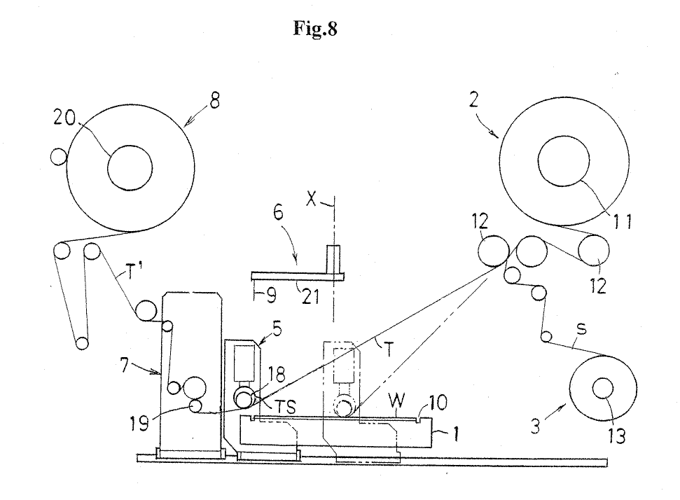

(3) In the foregoing embodiment, the intermediate sheet TS and the protective tape T are simultaneously fed out. The following configuration may also be adopted. For instance, as shown in FIG. 8, the intermediate sheet TS is configured into a tube body formed of the elastic body, such as silicone rubber, having a larger diameter than the joining roller 18 and a larger width than the diameter of the wafer W. In other words, the joining roller 18 is inserted into the tube intermediate sheet TS.

According to this configuration, the intermediate sheet TS rolls in a free state outside of the joining roller 18 in accordance with rolling of the joining roller 18. That is, the joining roller 18 applies pressure in the horizontal direction to the intermediate sheet TS prior to the protective tape T. Consequently, the intermediate sheet TS is loose in a free state and fed out in the direction where the roller rolls, thereby absorbing pressure in the horizontal direction. Accordingly, contraction stress may be suppressed that is accumulated in the protective tape T.

(4) In the foregoing embodiment, the protective tape T is joined to the wafer W, and thereafter is cut together with the intermediate sheet TS. The following configuration may also be adopted.

That is, the intermediate sheet TS and the protective tape T are pressed to be joined to the wafer W, and thereafter, the intermediate sheet TS is removed that is firstly laminated on the protective tape T, and then the protective tape T is cut along the contour of the wafer.

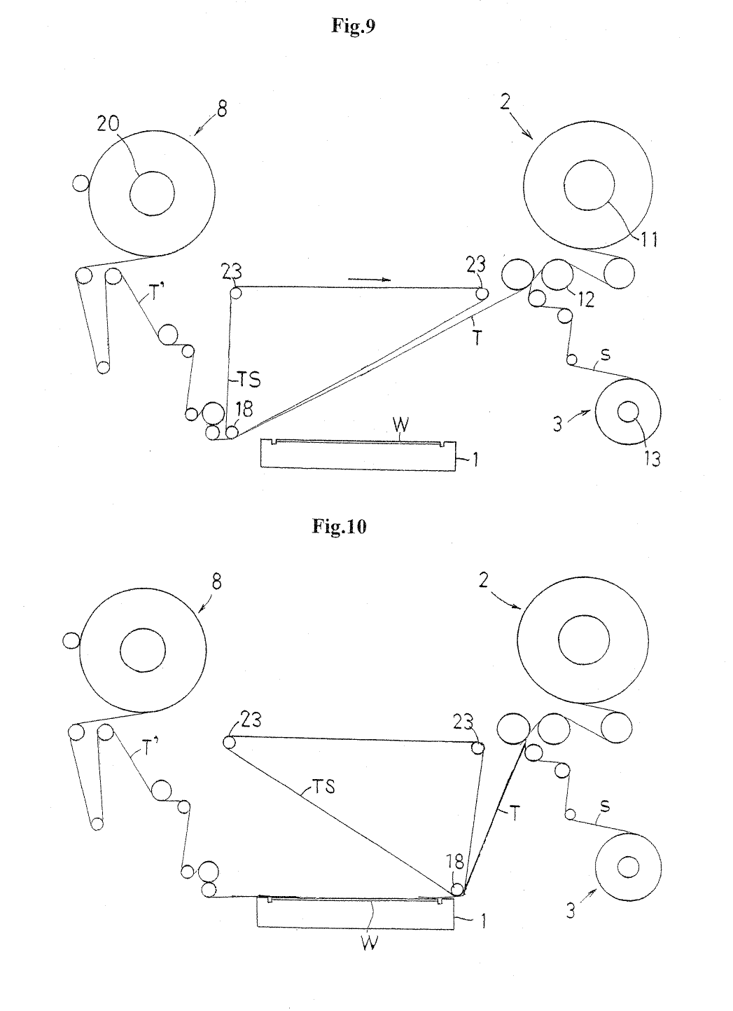

For instance, as shown in FIG. 9, the ring intermediate sheet TS having appropriate tension applied thereto is wound over two idling rollers 23 pivoted on the axis as to rotate freely and the joining roller 18. Here, appropriate tension falls within an extent in which the intermediate sheet TS is caught between the joining roller 18 and the protective tape T with no overload in accordance with rolling of the joining roller 18.

Specifically, the intermediate sheet TS rolls around the two idling rollers 23 and the joining roller 18 at an approximately same speed as the joining roller 18 that rolls from the tape joining start position in FIG. 9 to the tape joining termination position in FIG. 10. In this embodiment, the number of idling rollers 23 may not be limited to two, and may be one roller or three rollers or more.

Moreover, where the protective tape T is cut on the chuck table 1, the operator may remove the intermediate sheet TS from the joining roller 18 and the idling rollers 23 for preventing the intermediate sheet TS from interrupting a path where the protective tape cutting device 6 moves upward and downward shown in FIG. 1. Alternatively, the rollers 18, 23 may move in and out from the tape joining position and sides thereof on the chuck table 1 (the back side in FIGS. 9 and 10) while the intermediate sheet TS is wound around the joining roller 18 and the idling rollers 23.

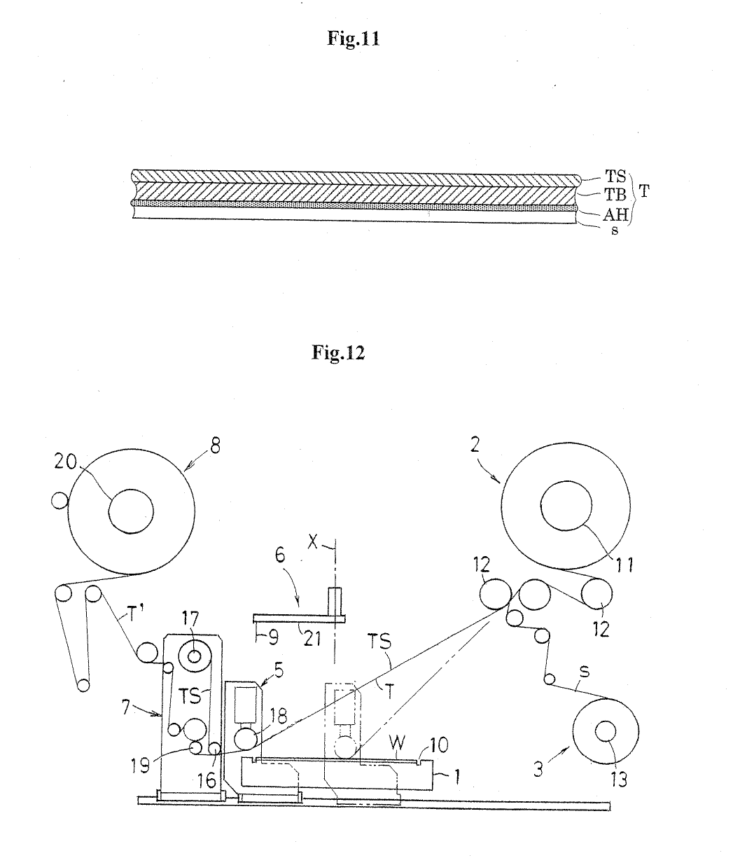

(5) In the foregoing embodiment, the protective tape T and the intermediate sheet TS are supplied from different original master rolls. Alternatively, the intermediate sheet TS and the protective tape T may be supplied simultaneously toward the wafer W from an original master roll in which the protective tape T and the intermediate sheet TS are wound together. In this configuration, the protective tape T has a separator s, an adhesive AH, a base material TB, and an intermediate TS laminated in this order from a lower layer, as shown in FIG. 11. Where the surface of the intermediate sheet TS is subjected to a release treatment, the separator s is not always needed.

In this configuration, it is preferable that, where the joining roller 18 rolls on the surface of the intermediate sheet TS, the intermediate sheet TS is not restrained upon exertion of pressure thereon in the rolling direction of the joining roller 18 (a surface direction of the base material.) In other words, it is preferable that the intermediate sheet TS is movable on the surface of the base material upon rolling of the joining roller 18. For obtaining this configuration, the intermediate sheet TS may for example be non-adhesive and only contact the surface of the base material TB. Alternatively, the intermediate sheet TS may have an adhesive of low adhesiveness applied thereto. Moreover, where the intermediate sheet TS has an adhesive AH applied thereto, a release treatment may be performed to the surface of the base material TB.

For instance, apparatus for joining the protective tape T to the wafer W may be configured as in FIG. 12. That is, an original master roll of the protective tape T having the intermediate sheet TS integrally wound thereon is attached to the supply bobbin 11. With this configuration, the protective tape joining process may be implemented as follows.

The separator s is separated during a process in which the protective tape T and the intermediate sheet TS are fed out and transported from the supply bobbin 11 via the guide roller 12. Thereafter, the intermediate sheet TS and the protective tape T are supplied to the joining position with the wafer W.

Next, as shown by an imaginary line in FIG. 12, the joining roller 18 in the joining unit 5 moves downward, and presses the intermediate sheet TS and the protective tape T downward while rolling on the wafer W in the forward direction (in the right direction in plane of FIG. 12). Consequently, the protective tape T is to be joined to the entire surface of the wafer W.

In this case, when the joining roller 18 rolls forward, frictional resistance in the tape joining direction and stretching force due to pressure on the peripheral surface of the joining roller 18 in a rolling direction (the base material surface direction) are exerted in the intermediate sheet TS contacting to the joining roller 18. On the other hand, the intermediate sheet TS is not restricted on the surface of the base material that forms the protective tape T. Consequently, the intermediate sheet TS is movable in the sheet longitudinal direction.

That is, only pressure downward in the perpendicular direction is exerted in the protective tape T without directly exerting frictional resistance and stretching force from the joining roller 18 in the protective tape T. Accordingly, the protective tape T is joined to the surface of the wafer with an extremely little contraction stress accumulated due to stretching force, etc.

When the joining unit 5 reaches a termination position, the protective tape cutting device 6 on standby on the upper side moves downward, and the cutter blade 9 pierces the intermediate sheet TS and the protective tape T on the cutter blade traveling groove 10 of the chuck table 1.

Next, the support arm 21 turns in a given direction, whereby the cutter blade 9 turns about a vertical axis X to cut the intermediate sheet TS and the protective tape T along the outer periphery of the wafer.

When cutting of the tapes along the outer periphery of the wafer is completed, the protective tape cutting device 6 moves upward into the original standby position. Next, the separation unit 7 moves forward to separate the remained unnecessary tape T′ after cutting out on the wafer W while winding up the unnecessary tape T′.

When the separating unit 7 reaches a termination position of the separation, the separating unit 7 and the joining unit 5 move in a reverse direction so as to return to the initial positions, respectively. Here, the collecting bobbin 20 winds up the unnecessary tape T′, and the tape supplying section 2 feeds out a given amount of the protective tape T. Moreover, the winding shaft 17 drives to wind up the intermediate sheet TS cut out and to feed out a given amount of the intermediate TS from the sheet supply section 4.

(6) In the foregoing embodiment, one intermediate sheet TS is interposed between the protective tape T and the joining roller 18. Alternatively, two or more intermediate sheets TS may be formed into a multi-layer construction. For obtaining this configuration, the intermediate sheets TS may contact to each other in a non-adhesive manner. Alternatively, the intermediate sheets TS may temporarily be fixed via an adhesive of low adhesiveness.

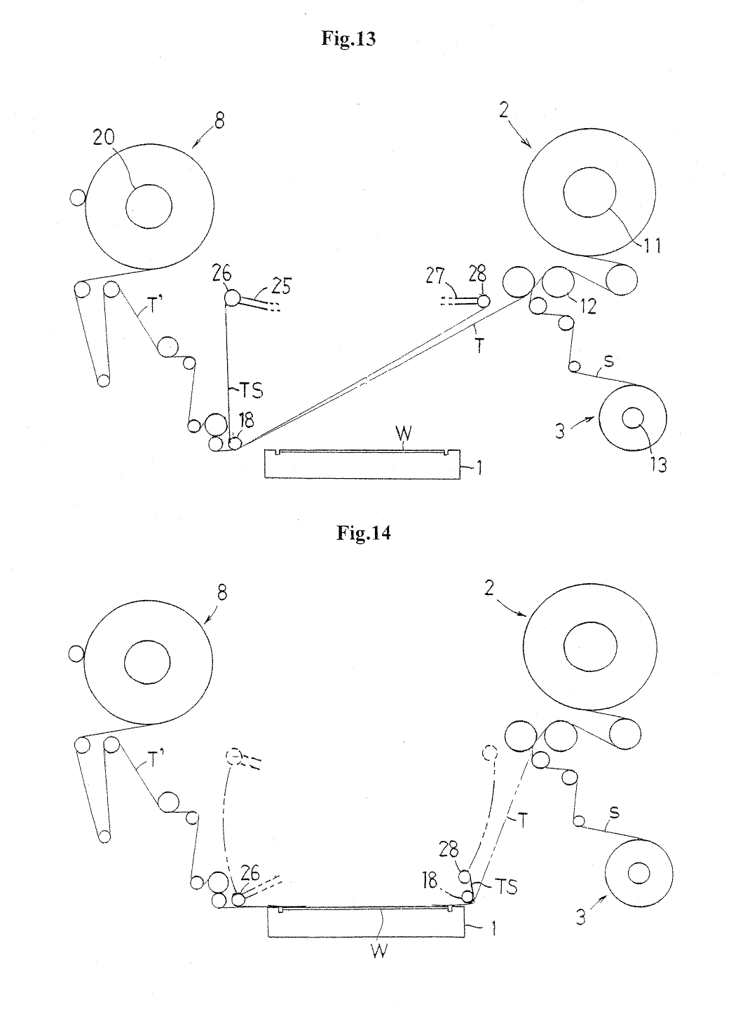

(7) In each foregoing embodiment, the intermediate sheet TS may be reusable. For instance, as shown in FIG. 13, the intermediate sheet TS is suspended in a tensioned condition over a driving roller 26 at a front end of a swinging arm 25 provided above the joining start position of the protective tape T and a roller 28 fixed at a front end of a swinging arm 27 provided above the joining termination position.

Next, description will be given of a series of operations of joining the protective tape T with the apparatus in this embodiment.

The joining roller 18 stats rolling upon starting of joining the protective tape T, and simultaneously the swinging arm 25 swings downward to place the roller 26 into a position corresponding to the standby position of the joining roller 18. Here, during swinging of the arm 25, the intermediate sheet TS is wound up so as not to come loose from the joining roller 18 and the protective tape T joined to the wafer W is prevented from removal. In addition, the swinging arm 28 is in an upper standby position.

The joining roller 18 rolls, and the feed-out angle of the protective tape T varies. Accordingly, the swinging arm 27 swings downward such that the feed-out angle follows an angle of the intermediate sheet TS.

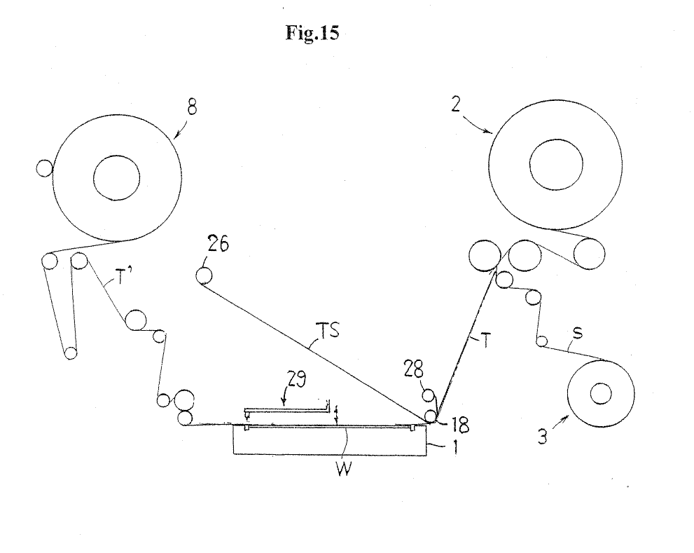

When the joining roller 18 reaches the termination position, the swinging arm 25 on the start position side returns to the upper standby position as shown in FIG. 15. At this time, the intermediate sheet TS is separated from the surface of the protective tape T. Subsequently, the swinging arm 25 moves backward and forward from the protective tape joining position to outside of the wafer (in the depth direction in plane of figures) where the intermediate sheet TS is not prevented from swinging downward. In addition, a liftable cutting unit 29 moves downward to its joining position, whereby a cutter blade thereof having a tip end directed downward pierces the protective tape T.

Under this state, the cutting unit 29 turns about the wafer to cut the protective tape T along the contour of the wafer. Upon cutting is completed, the cutter unit 29 moves upward to returns to its standby position. Simultaneously, the joining roller 18 returns to its starting position, whereby the unnecessary protective tape T′ after cut out is separated. The joining roller 18 slightly moves upward upon reaching its starting position, and the unnecessary protective tape T′ is wound and collected.

Thus, a round of basic joining operation is completed as mentioned above. The similar operation is to be repeated hereinafter.

(8) In each foregoing embodiment, the strip protective tape T is joined to the wafer W and is cut out. Alternatively, a protective tape PT pre-cut into the shape of the wafer W may be supplied to a joining position while being joined to the strip separator s with a give pitch.

In this case, the separator s is wound and collected so as to be folded back with an edge member for reverse, whereby the protective tape T having the separator s separated therefrom is supplied to the joining position. Here, the protective tape T is joined to the wafer W while the intermediate sheet TS fed in a similar manner as the protective tape T from another path and the protective tape T are pressed with the joining roller 18.

Moreover, the intermediate sheet TS in a strip shape may be supplied. Alternatively, an intermediate sheet TS cut into the same shape as the protective tape T may be supplied having the protective tape T laminated thereon in advance.

Moreover, in this embodiment, the strip separator s separated from the pre-cut protective tape T may be guided between the joining roller 18 as the joining position of the protective tape T and the wafer W to be used as the intermediate sheet TS.

Moreover, in this embodiment, the protective tape T may be guided between the joining roller 18 as the joining position thereof and the wafer W from an original master roll in which the pre-cut protective tape T is wound up while being interposed between the strip separator s and the strip intermediate sheet TS.

### INDUSTRIAL UTILITY

As described above, this invention is suitable for joining a protective tape to a semiconductor wafer while extension of the protective tape is suppressed upon joining of the protective tape.

1. A method of joining a protective tape to a semiconductor wafer with use of a joining member, comprising the step of:
joining the protective tape to the semiconductor wafer through relative movement of the joining member and the semiconductor wafer while an intermediate sheet is interposed between the joining member and the protective tape.

2. The method of joining the protective tape according to claim 1, wherein
the joining member is a joining roller, and the joining roller and the semiconductor wafer move relative to each other in a horizontal direction along the surface of the wafer.

3. The method of joining the protective tape according to claim 1, wherein
the joining member is a member having a curved press surface that bends outward toward the semiconductor wafer, and the joining member swings, thereby pressing the curved press surface from one end to the other end thereof against the intermediate sheet.

4. The method of joining the protective tape according to claim 1, wherein
the protective tape is strip, and the protective tape is integrated with the strip intermediate sheet for supply of them into a joining position.

5. The method of joining the protective tape according to claim 1, wherein
the protective tape is joined to the semiconductor wafer, and thereafter, the intermediate sheet and the protective tape are cut along the contour of the semiconductor wafer while the intermediate sheet is laminated on the protective tape.

6. The method of joining the protective tape according to claim 1, wherein
the protective tape is cut in advance along the contour of the semiconductor wafer.

7. The method of joining the protective tape according to claim 5, wherein
the protective tape is joined to the semiconductor wafer, and thereafter, the intermediate sheet is removed and the protective tape is cut along the contour of the semiconductor wafer.

8. The method of joining the protective tape according to claim 5, wherein
the protective tape has a separator on an adhesive surface thereof, and the separator removed from the protective tape is guided between the protective tape and the joining member for use as the intermediate sheet.

9. The method of joining the protective tape according to claim 7, wherein
the intermediate sheet is suspended in a tensioned condition over a protective tape joining position as to follow a feed-out angle of the protective tape that varies through rolling of the joining roller.

10. The method of joining the protective tape according to claim 2, wherein
the intermediate sheet is a tube body having a diameter larger than that of the joining roller and a width larger than the contour of the semiconductor wafer, and
the protective tape is joined to the surface of the wafer while the joining roller and the semiconductor wafer move relatively in the horizontal direction along the surface of the wafer with the joining roller being inserted into the tube body.

11. The method of joining the protective tape according to claim 1, wherein the protective tape may be joined to the semiconductor wafer while the joining roller rolls on a ring intermediate sheet that is wound over at least one pivoted idling roller and the joining roller.

12. The method of joining the protective tape according to claim 1, wherein
the intermediate sheet is suspended in a tensioned condition over a driving roller at a front end of a swinging arm and a fixed roller at a front end of an arm each provided above the semiconductor wafer;
the driving roller swings downward to a roller rolling position prior to rolling of the joining roller on the intermediate sheet, and the driving roller winds up the intermediate sheet to apply given tension to the intermediate sheet; and
the protective tape is joined to the semiconductor wafer while the fixed roller swings downward with maintained given tension to the intermediate sheet in accordance with variations in movement distance of the joining roller during rolling of the joining roller on the protective tape via the intermediate sheet.

13. A protective tape used in the method of joining the protective tape according to claim 1, comprising:
an intermediate sheet that allows movement on a surface of a base material in a surface direction of the base material upon exertion of pressure.
